(19) United States
(12) Patent Application Publication
(10) Pub. No.: US 2003/0015768 A1
(43) Pub. Date: Jan. 23, 2003

(54) Structure and method for microelectromechanical system (MEMS) devices integrated with other semiconductor structures

(75) Inventors: Bruce Allen Bosco, Phoenix, AZ (US); Steven James Franson, Scottsdale, AZ (US); John E. Holmes, Scottsdale, AZ (US); Nestor J. Escalera, Gilbert, AZ (US); Rudy M. Emrick, Gilbert, AZ (US); Stephen K. Rockwell, Mesa, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/909,936

(22) Filed: Jul. 23, 2001

(51) Int. Cl. H01L 27/15; H01L 31/12; H01L 33/00; H01L 29/00; H01L 31/0328

(52) U.S. Cl. 257/528; 257/190

(57) ABSTRACT

Microelectromechanical (MEMS) devices are integrated with high frequency devices on a monolithic substrate or wafer. High quality epitaxial layers of monocrystalline materials can be grown overlying monocrystalline substrates such as large silicon wafers by forming a compliant substrate for growing the monocrystalline layers. MEMS devices, such as a switch, a variable capacitance device or a temperature control structure, are formed in the base monocrystalline substrate. High frequency devices, such as transistors or diodes, are formed in the overlaying layer of monocrystalline materials.

### FIELD OF THE INVENTION

This invention relates generally to microelectromechanical system (MEMS) semiconductor structures and high frequency devices and to a method for their fabrication, and more specifically to the fabrication and use of MEMS semiconductor structures, devices, and integrated circuits that include a monocrystalline material layer comprised of semiconductor material, compound semiconductor material, and/or other types of material such as metals and non-metals.

### Background of the Invention

MEMS structures are manufactured with silicon using CMOS or other processes. The MEMS structures may be integrated on a substrate with other silicon semiconductor devices, such as transistors or amplifiers. However, silicon semiconductor devices have a limited range of frequency response or use.

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 24 and 25 illustrate schematically, in cross section, device structures that can be used in accordance with various embodiments of the invention;

FIGS. 26-30 include illustrations of cross-sectional views of a portion of an integrated circuit that includes a compound semiconductor portion, a bipolar portion, and an MOS portion in accordance with what is shown herein;

FIGS. 31-37 include illustrations of cross-sectional views of a portion of another integrated circuit that includes a semiconductor laser and a MOS transistor in accordance with what is shown herein.

FIG. 38 illustrates a cross-sectional view of a portion of an integrated circuit that includes a compound semiconductor portion and a MEMS structure portion in accordance with what is shown herein.

FIGS. 39-42 illustrate a portion of an integrated circuit that includes an optical device and a MEMS device in accordance with what is shown herein;

FIGS. 43-45 illustrate a portion of a monolithic device that includes an selectable Bragg grating device in accordance with what is shown herein; and

FIGS. 46-48 illustrate a portion of an integrated circuit that includes an optical device and a MEMS device in accordance with what is shown herein.

FIGS. 49, 50, 53 and 54 include illustrations of cross-sectional views of a portion of an integrated circuit that includes MEMS structure in accordance with what is shown herein;

FIGS. 51-52 and 55-57 include illustrations of cross-sectional views of a portion of an integrated circuit that includes a compound semiconductor portion and a MEMS portion in accordance with what is shown herein;

FIG. 58 illustrates a flow chart summarizing the process of one embodiment for fabricating a semiconductor structure;

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

Microelectromechanical (MEMS) devices are advantageously integrated with high frequency integrated circuit components. MEMS operate more efficiently, provide lower noise and allow higher power operation than electronic switches. Integration of MEMS with high frequency integrated circuit components on one semiconductor structure may reduce manufacturing costs and reduce losses from connections between components. For example, MEMS switching or variable capacitance devices are integrated with a gallium arsenide (GaAs) based amplifier or transistor on a monolithic semiconductor structure or wafer. MEMS devices are manufactured using CMOS techniques on semiconductor materials, such as silicon. To integrate silicon or other MEMS structures with some high frequency integrated circuit components, a semiconductor structure providing both types of materials is used.

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer.

Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

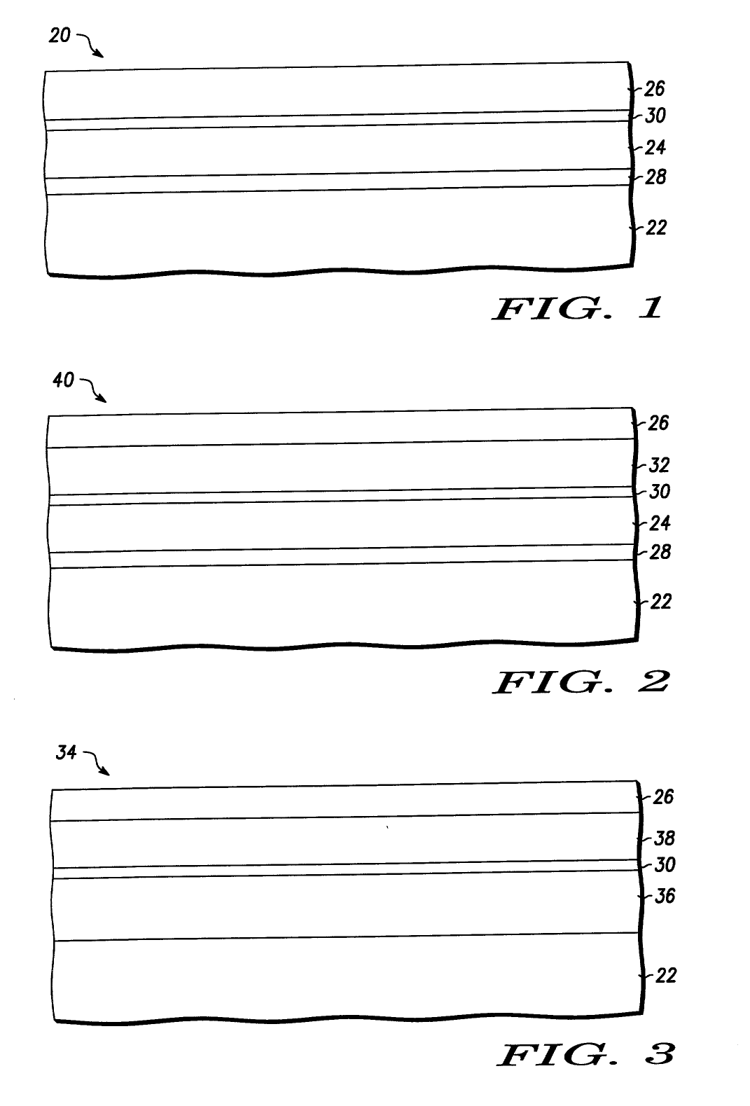

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 m and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials.

By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 m and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2.

In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}, TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

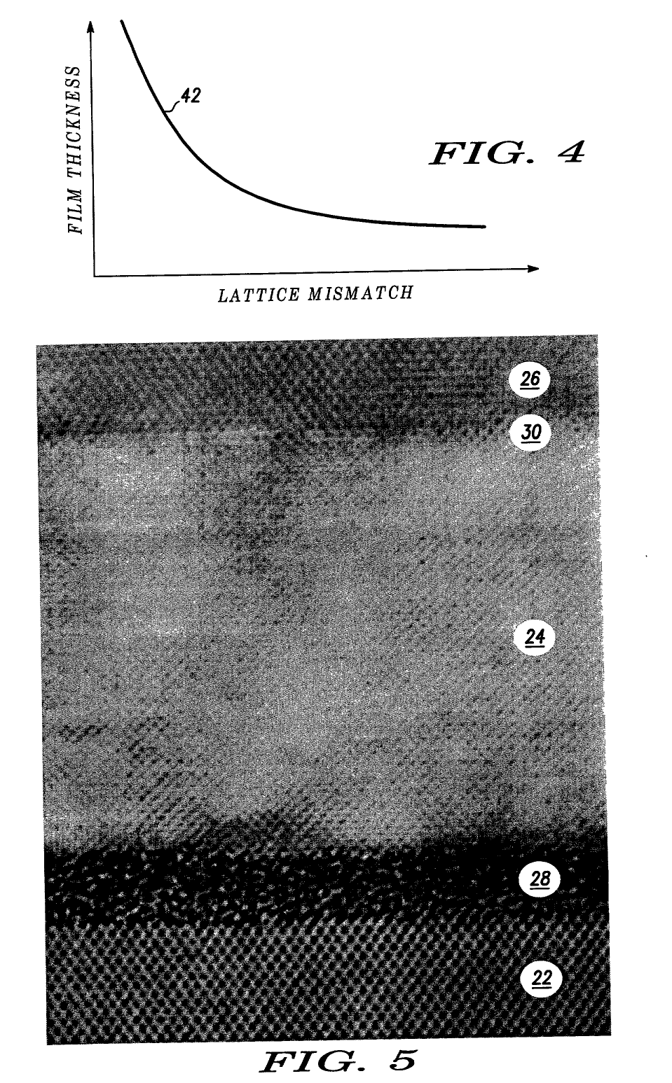

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

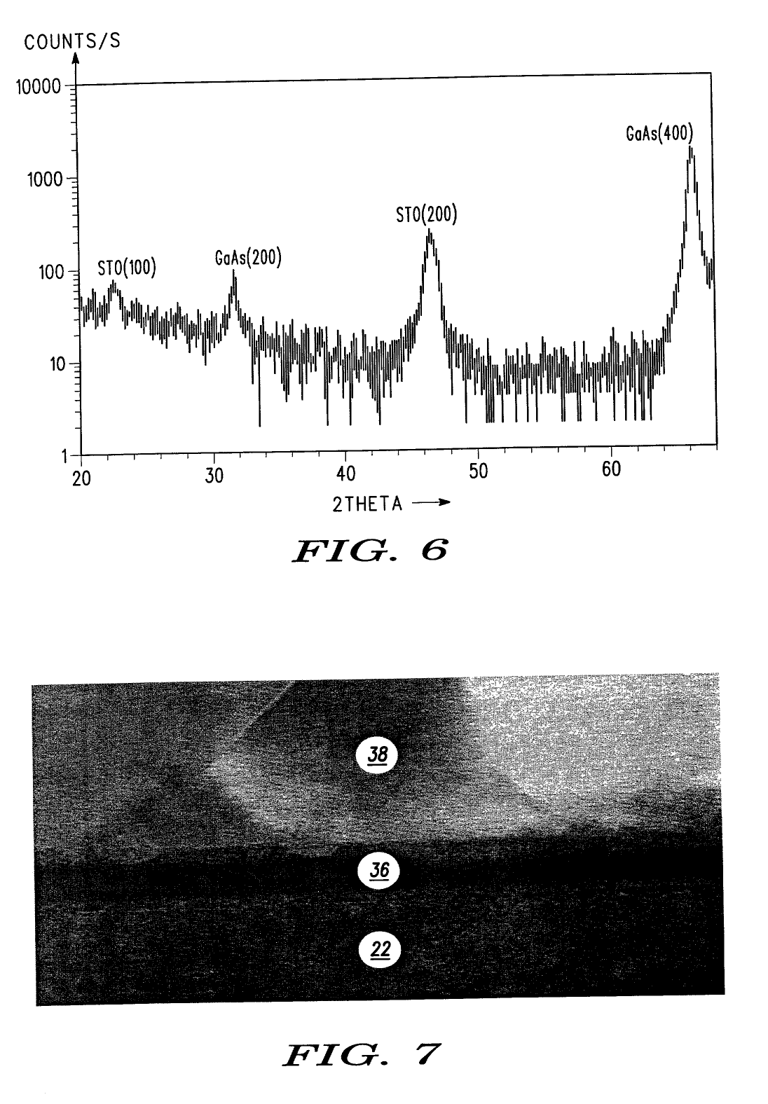

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

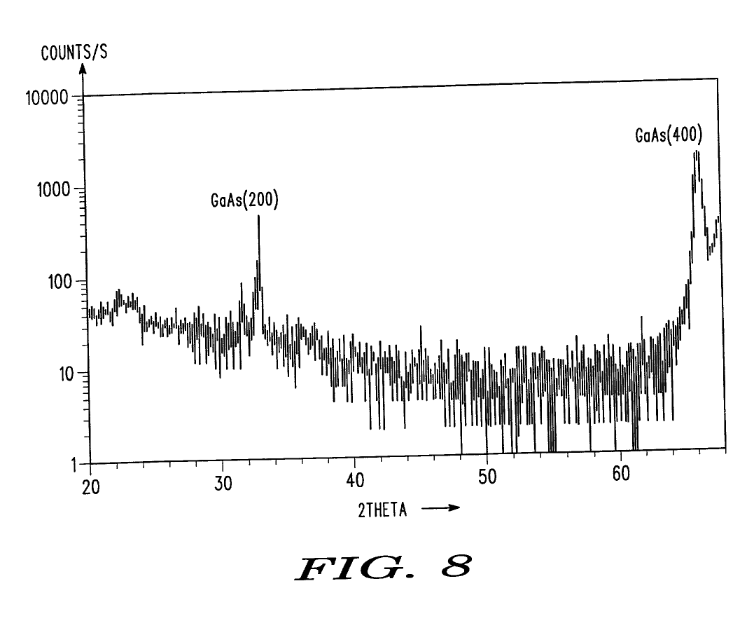

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

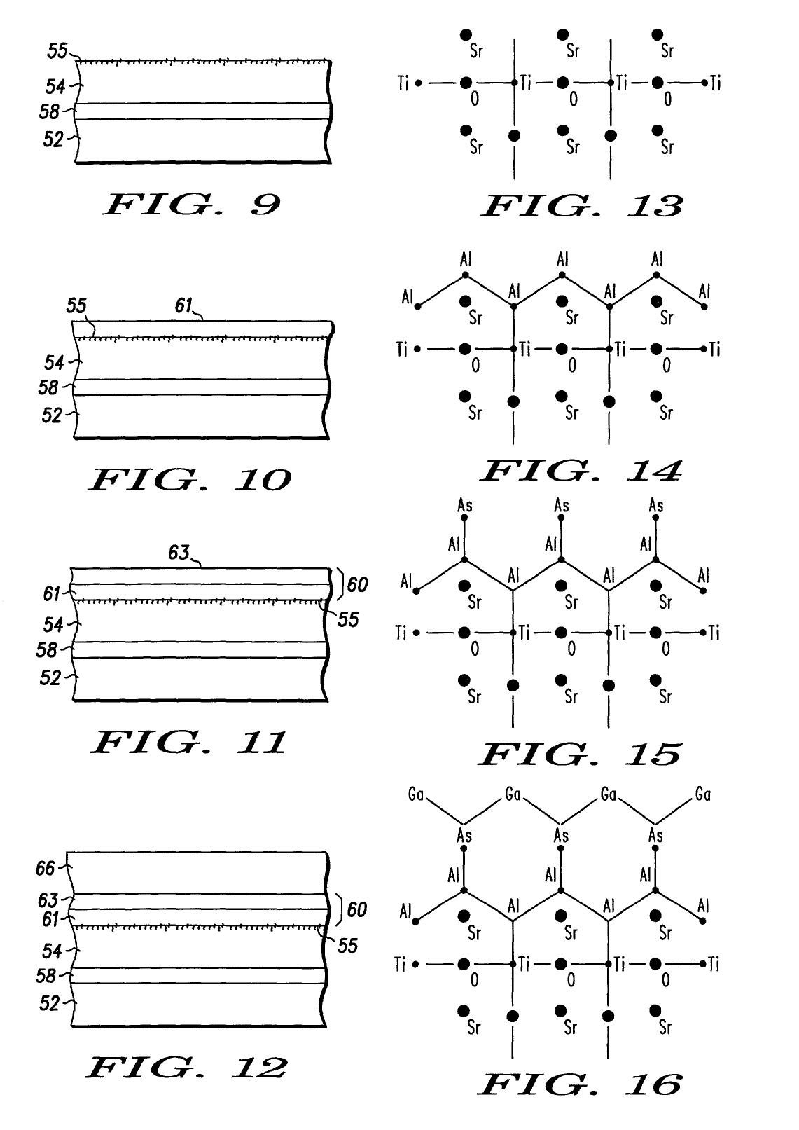

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}<(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, MEMS devices or integrated circuits. Alkaline earth metals such as those in Group IIA are those elements preferably used to form the capping surface of the monocrystalline oxide layer 54 because they are capable of forming a desired molecular structure with aluminu.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

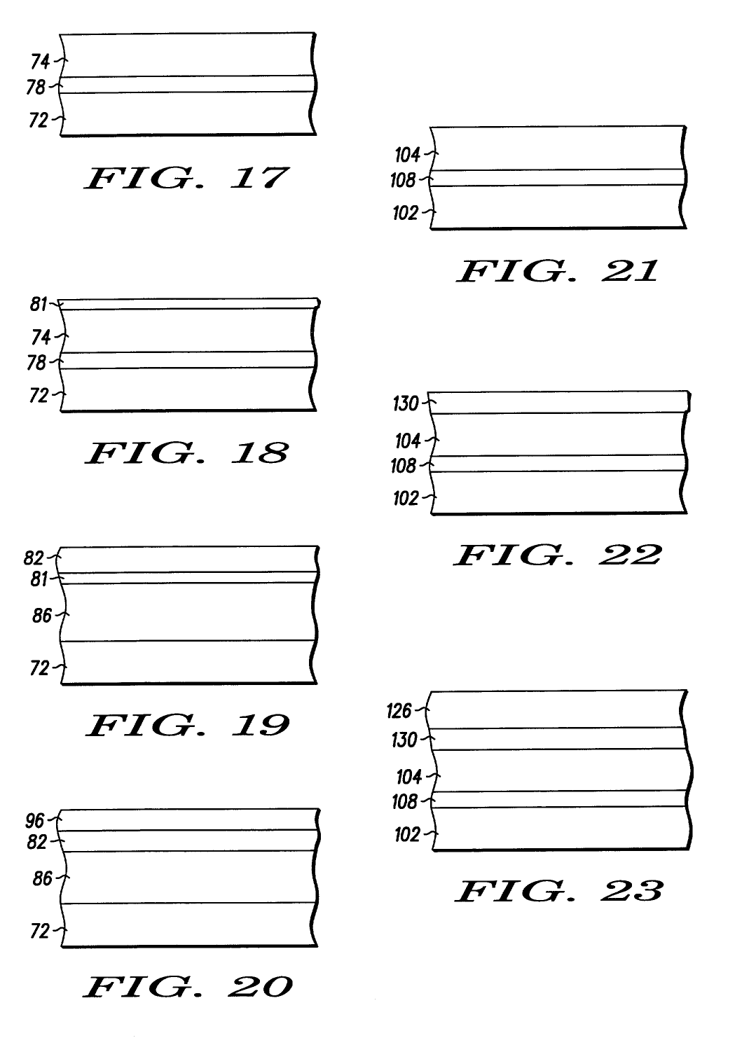

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al-As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices, MEMS structures and integrated circuits including other layers such as metal and non-metal layers. More specifically, the invention includes structures and methods for forming a compliant substrate which is used in the fabrication of semiconductor structures, devices, MEMS structures and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

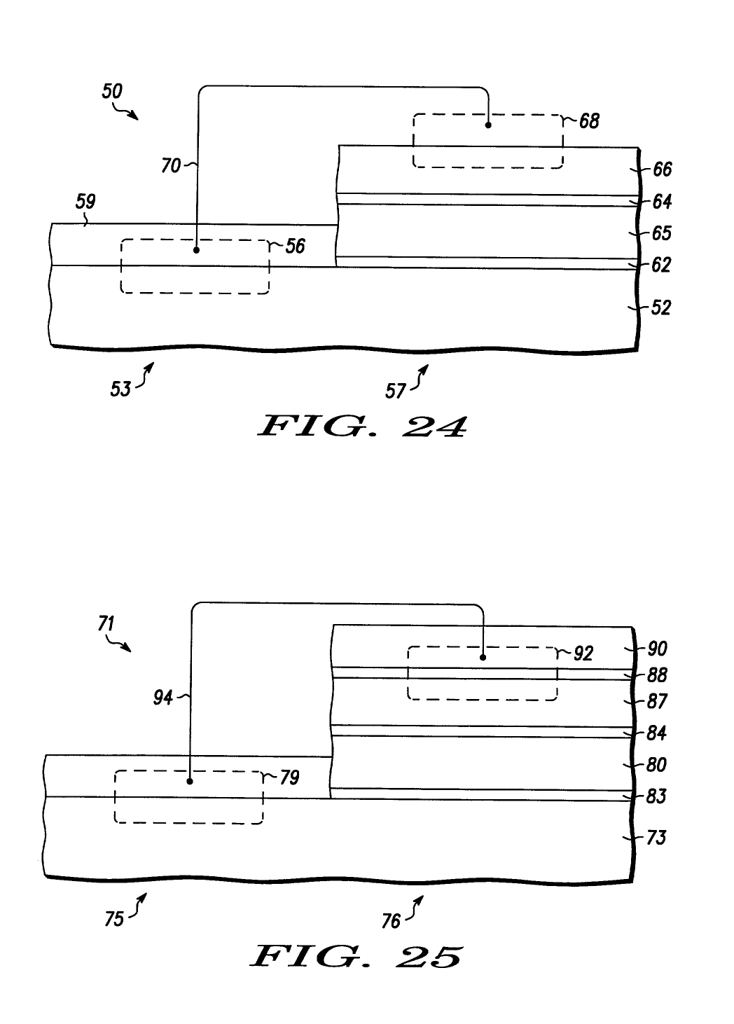

FIG. 24 illustrates schematically, in cross section, a device structure 50 in accordance with a further embodiment. Device structure 50 includes a monocrystalline semiconductor substrate 52, preferably a monocrystalline silicon wafer.

Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. In other embodiments, the component 56 comprises a microelectromechanical (MEMS) structure. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 110 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, PHEMT, MEMS structure or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical or MEMS component schematically illustrated by the dashed line 79 is formed in region 75 using conventional silicon device processing techniques commonly used in the semiconductor industry or MEMS formation techniques, such as CMOS processing. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 86 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88 and/or a MEMS structure. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

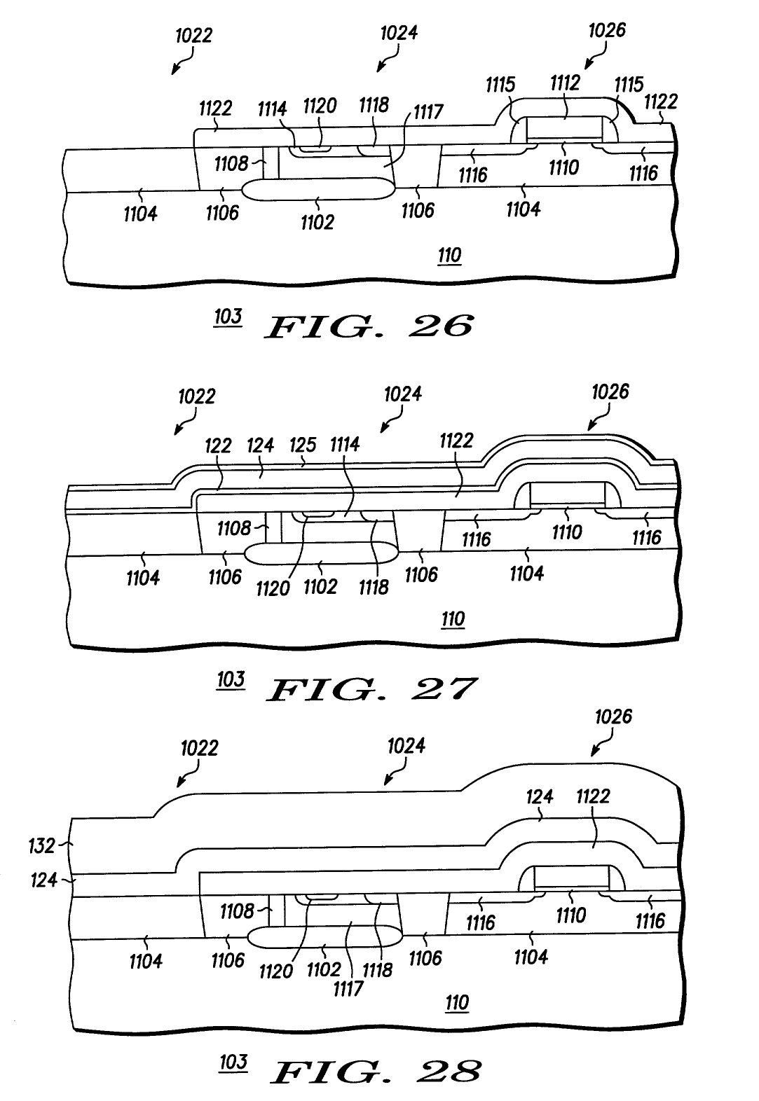

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

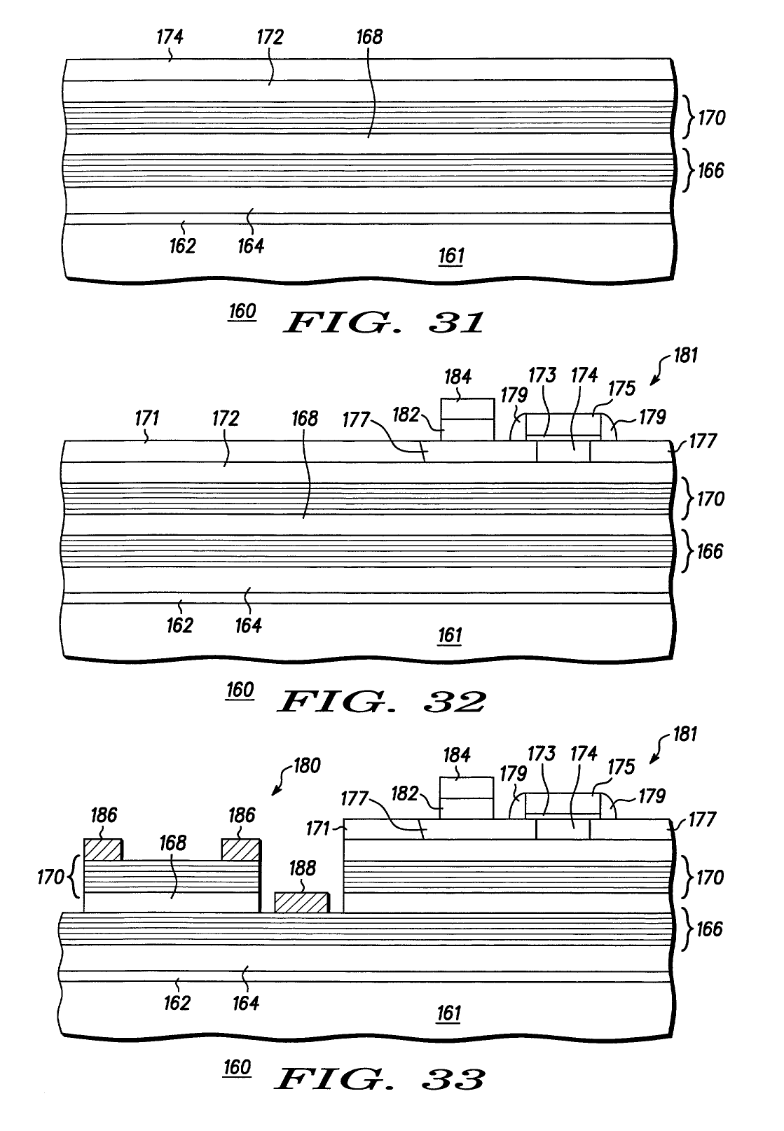

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5. A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped.

If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as MEMS structure, resistors, capacitors, diodes, and the like, may be formed in one or more of the portions 1022, 1024, and 1026.

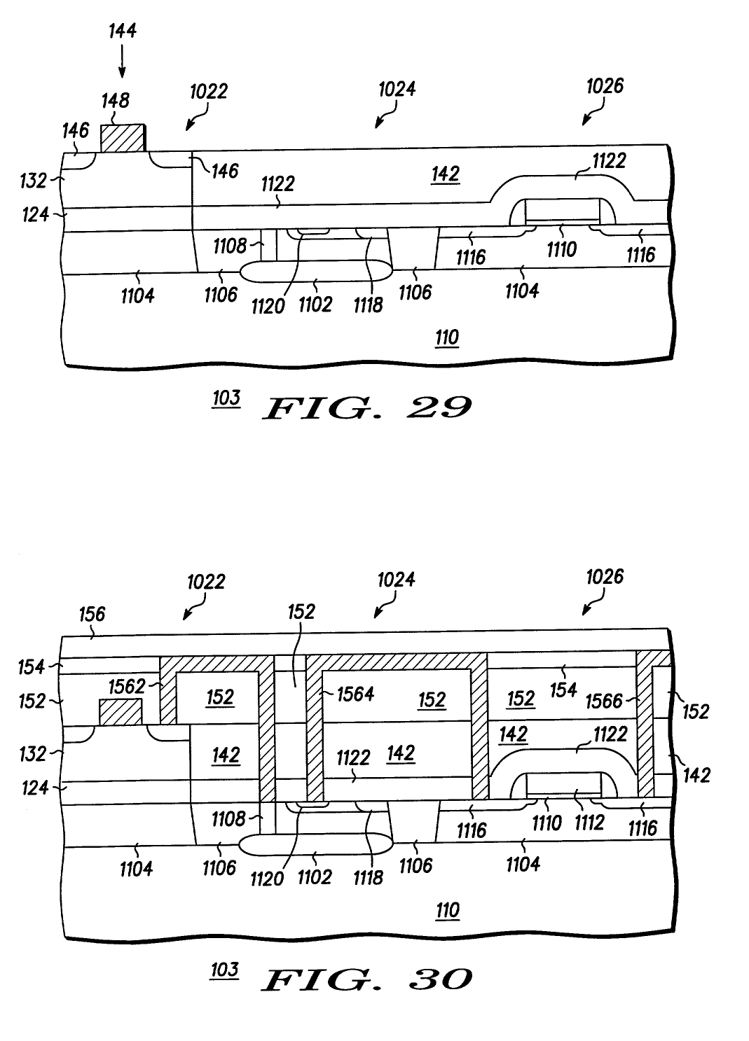

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P⁺ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping.

Regardless how the P+ upper portion 184 is formed, the insulating layer is then removed to form the resulting structure shown in FIG. 32. The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

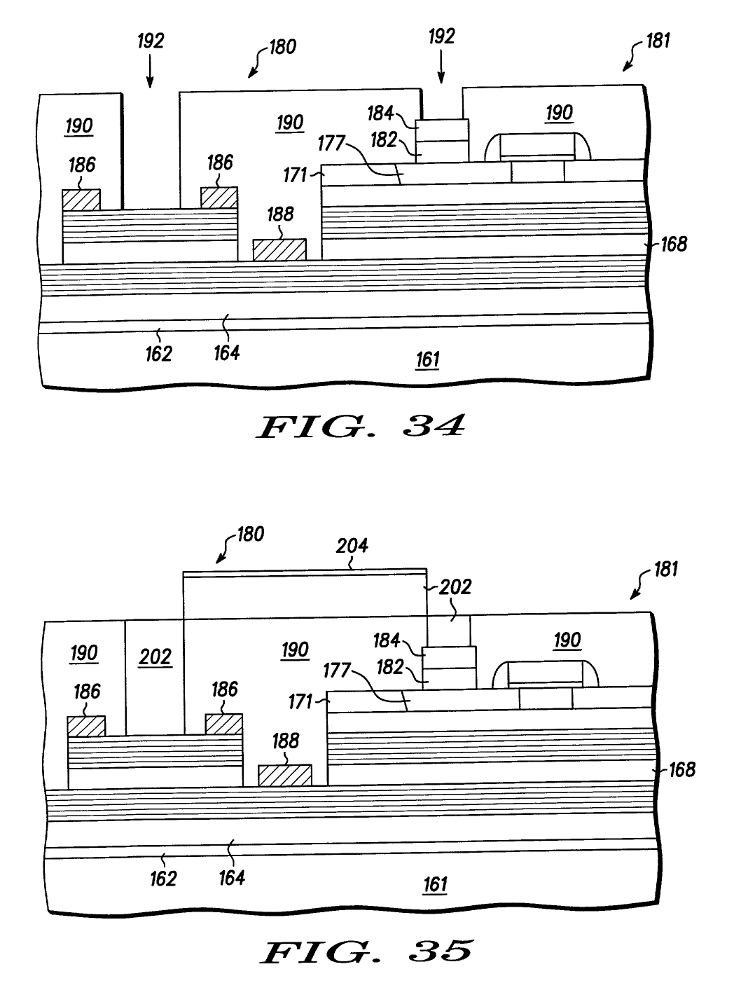

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

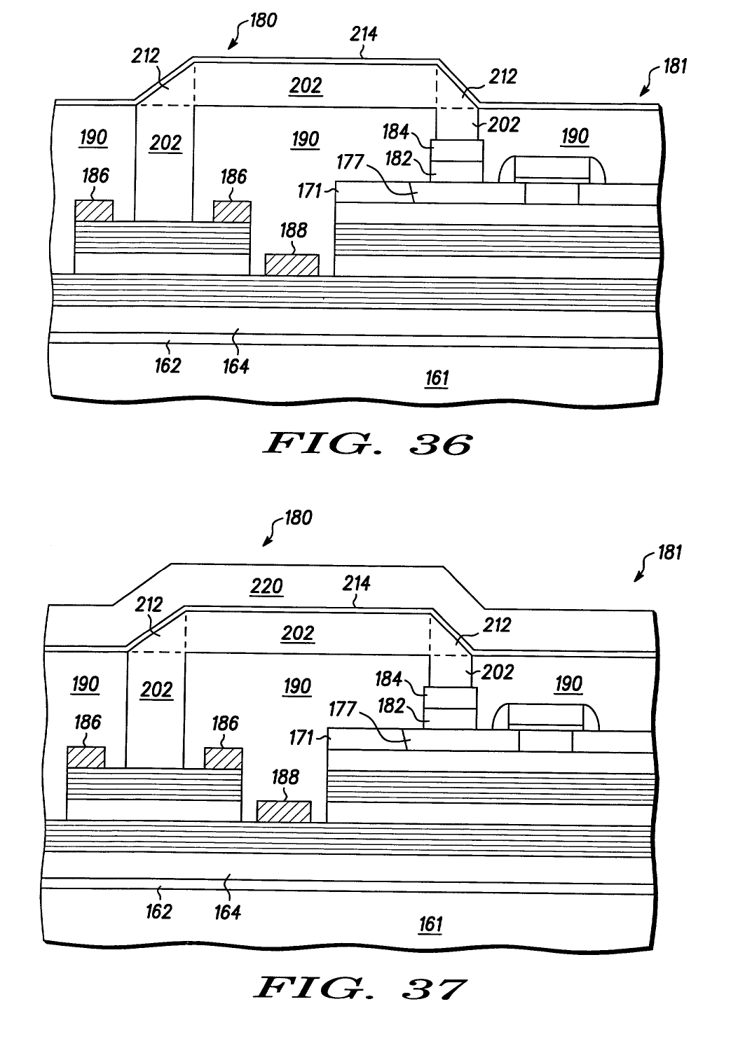

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include MEMS structures, such as a moveable mirror, other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, MEMS structure or the like, and the Group IV semiconductor can include digital logic, memory arrays, MEMS structure and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical or MEMS components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc. or electromechanical, such as MEMS structures.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc. Mechanical connections may also be provided.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

As discussed below, a MEMS switch structure comprising a mirror may be used to switchably connect a plurality of optical sources and/or detectors in different configurations. For example, an optical source is optically connected to one of two detectors in response to a position of a MEMS switch.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground.

In most known applications, power supply and ground connections are usually well-protected by circuitry to prevent harmful external signals from reaching the composite integrated circuit. A communications ground may be isolated from the ground signal in communications connections that use a ground communications signal.

In yet other embodiments, a MEMS structure is integrated on the monolithic structure having the compound semiconductor portion and a Group IV semiconductor portion described above. The MEMS structure is formed in one or more of the various layers discussed above, such as a silicon substrate layer, a compound semiconductor layer, an amorphous oxide material, a monocrystalline perovskite oxide material or combinations thereof.

None, one or more additional semiconductor components may be integrated with the MEMS structure. For example, the MEMS structure is formed in a silicon substrate. Additional analog or digital components, such as CMOS devices, resistors, transistors or other devices discussed herein, can also be formed in the silicon substrate. Additional components, such as transistors or other devices for operation associated with high frequencies, can be formed in the compound semiconductor layer. The integration of MEMS structures with semiconductor devices using different monocrystalline layers provides a broader range of integrated applications.

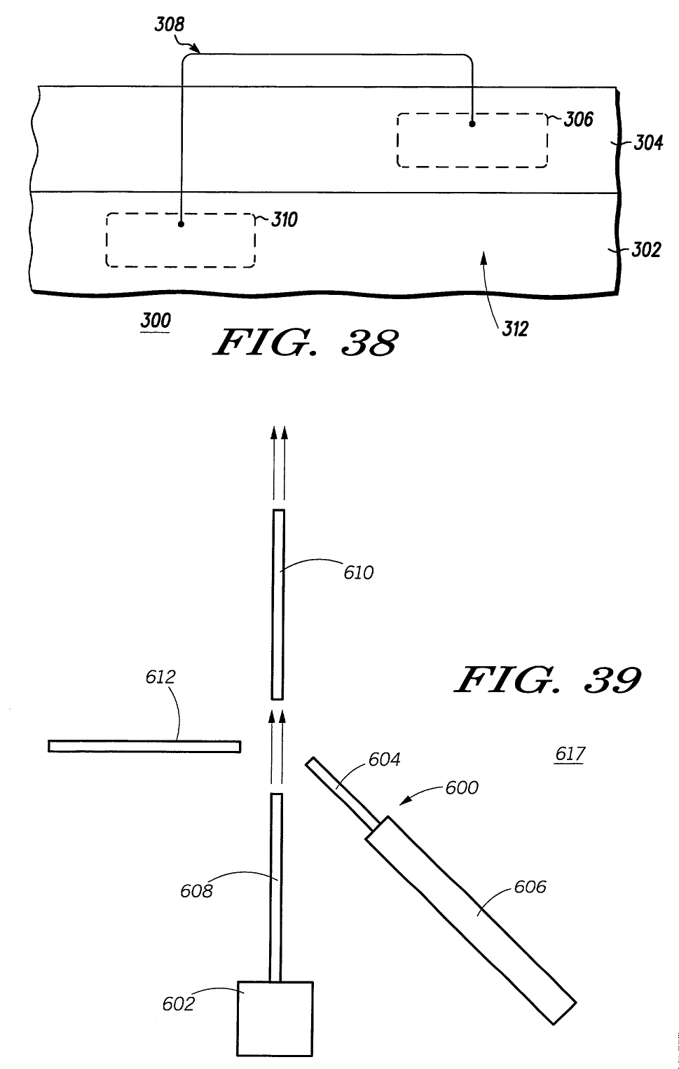

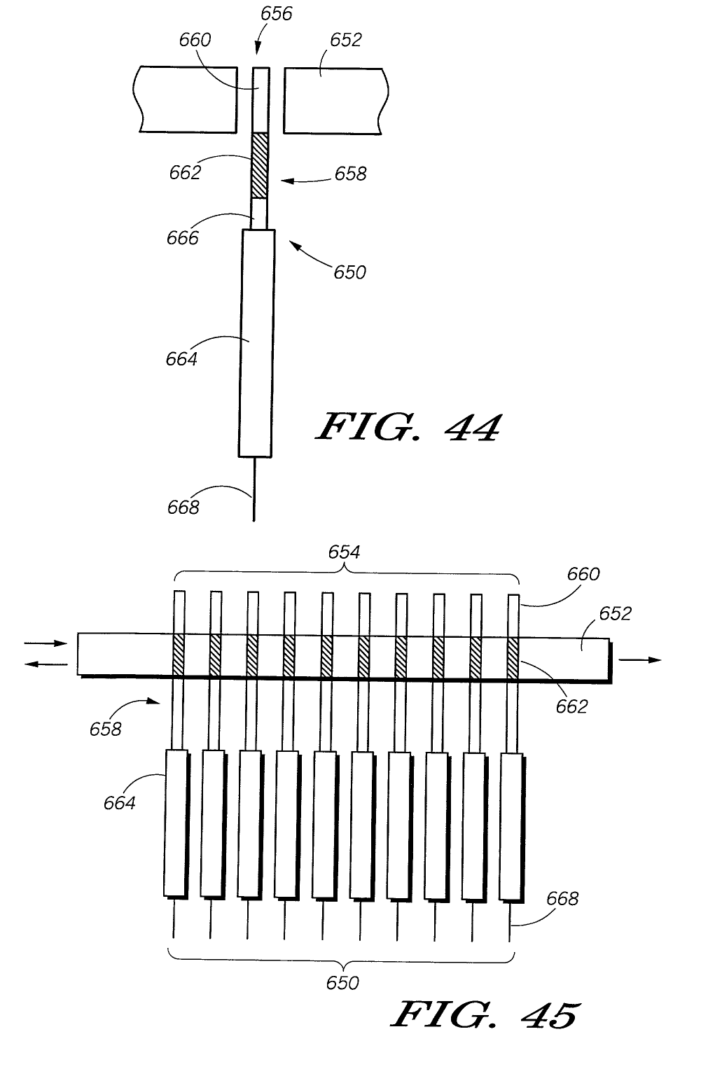

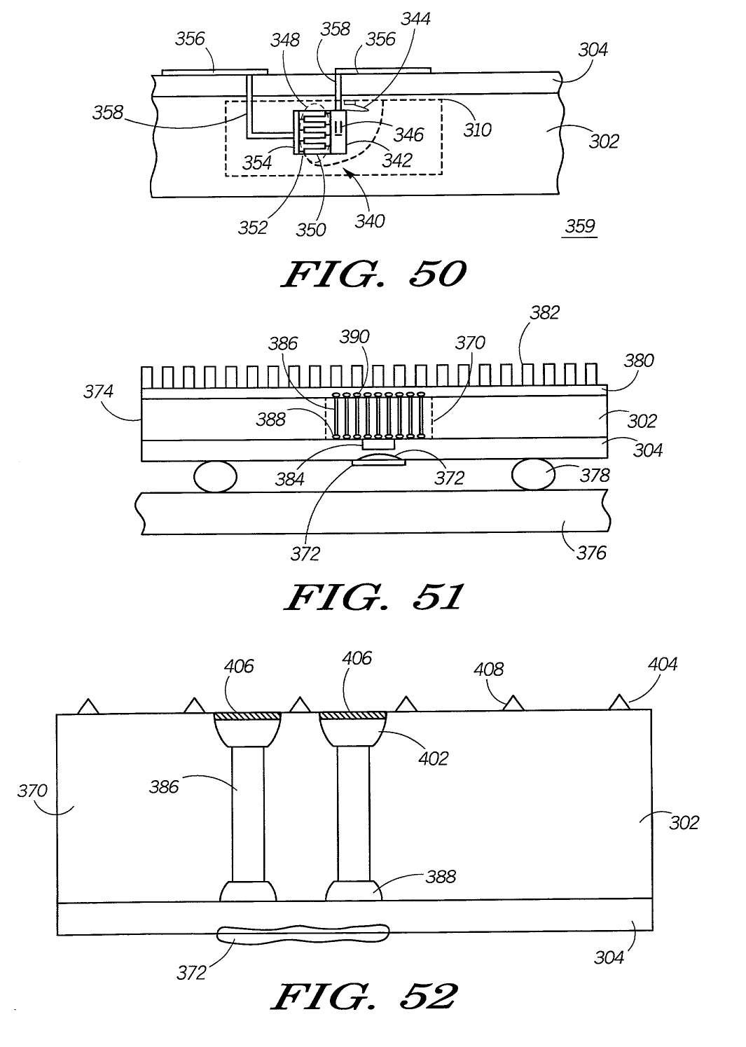

FIGS. 38-58 illustrate embodiments incorporating MEMS structures. Different types of MEMS structures may be used. The embodiments illustrated in FIGS. 39-48 include MEMS devices integrated with optical devices. The embodiments illustrated in FIGS. 49-57 include MEMS (a) switching and tuning devices (FIGS. 49 and 50) and (b) active and passive temperature control structures (FIGS. 51-57). Other MEMS structures, such as membranes for pressure sensing or acoustic signal generation, moveable plates for temperature or pressure sensing, or moving or rotating structures, may be used.

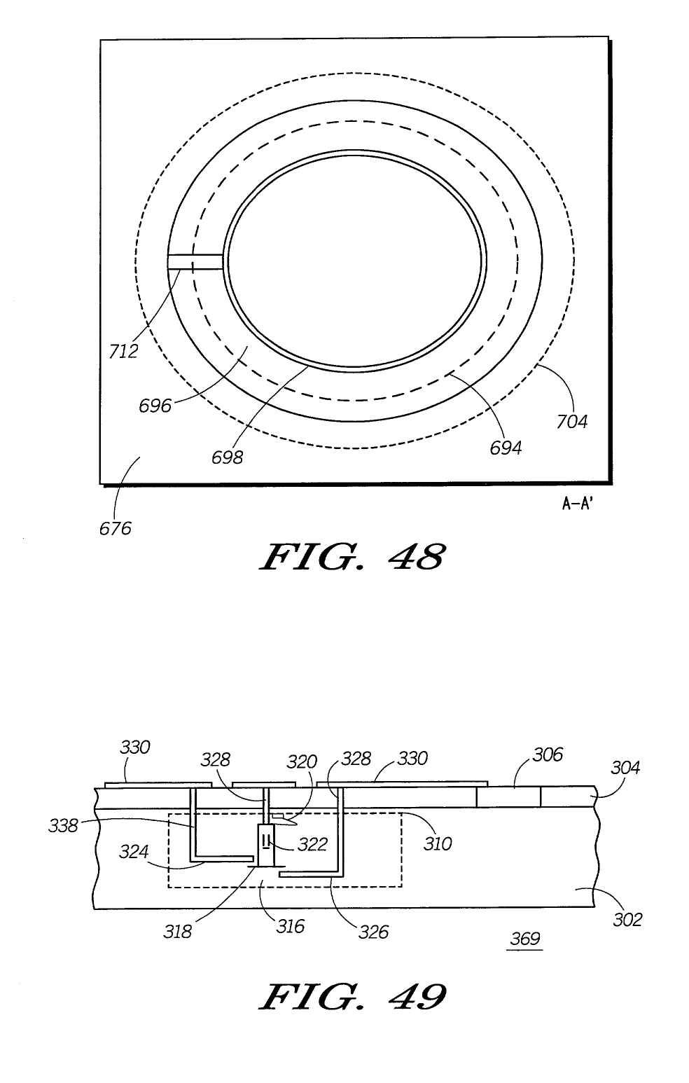

FIG. 38 includes an illustration of a cross-section view of a portion of an integrated circuit 300 that includes a monocrystalline substrate or wafer 302, such as a silicon substrate, and a monocrystalline compound semiconductor layer 304. The amorphous intermediate layer and accommodating buffer layer, such as amorphous oxide material, monocrystalline perovskite oxide material or others previously described, are omitted from the illustrations of FIGS. 48-57 for clarity. However, these intermediate and buffer layers are included and function as described above for making a transition between the compound semiconductor layer 304 and the monocrystalline Group IV semiconductor layer 302. Additional layers of monocrystal, buffer or amorphous material may be provided as discussed above.

The monocrystalline compound semiconductor layer 304 includes one or more semiconductor components indicated by dashed line 306. Semiconductor component 306 can be formed by processing steps conventionally used in the fabrication of gallium arsenide or other III-V compound semiconductor material devices as described above. Semiconductor component 306 can be any active or passive component, such as a semiconductor laser, light emitting diode, photodetector, heterojunction bipolar transistor (HBT), high frequency MESFET, PHEMT, MEMS structure or other component that utilizes and takes advantage of the physical properties of compound semiconductor materials. Preferably, the semiconductor component 306 is one of a transistor, amplifier, transceiver, tunable oscillating circuit, a dielectric resonator or semiconductor component of a tunable filter.

A metallic conductor schematically indicated by the line 308 can be formed to electrically couple semiconductor component 306 and MEMS structure 310, thus implementing an integrated device that includes at least one device formed in monocrystalline compound semiconductor layer 304 and at least one device formed in monocrystalline silicon substrate 302. In alternative embodiments, the monocrystalline substrate 302 comprises Group IV materials other than or in addition to silicon, but will be described below as a silicon substrate for simplicity.

The MEMS structure 310 comprises an electromechanical device where at least one mechanical or movable element of the component or device is manufactured (micro-machined) utilizing semiconductor-style processing. For example, the MEMS structure 308 comprises one or more of a switch, a variable capacitance structure, a moveable device, a tube, a pump, a membrane or other MEMS device. Other MEMS structures include, for example, inductors, relays, optical-fiber switches, phase-shifters, connectors (electrical, optical, hydraulic and pneumatic), contactless capacitive switch arrays, fuses and circuit-breakers, as well as valves and biometric user-identification devices such as fingerprint pressure-sensing chips.

The MEMS structure 310 can incorporate moving members such as deflecting cantilevers, deflecting diaphragms, rotating disks, etc. as are known to the micro-mechanical art. For example, deformable structures responsive to temperature or other environmental characteristics are made. The deformable structures vary in a reproducible and predictable way with temperature, pressure, and/or other properties. The MEMS structure 310 can also incorporate a moving gas or fluid as in a micro-fluidic or micro-pneumatic device. The moving members of such devices can move by distortion, deformation, translation, deflection, rotation, torsion, capillary stress or other motion. Further, micro-mechanical devices can incorporate at least one of electrostatic, magnetic, piezoelectric, electromagnetic, inertial, pneumatic, hydraulic or thermal micro-actuation mechanisms. Prototype micro-mechanical switches have used electrostatic, magnetic, electromagnetic, thermal and inertial micro-actuation means. Other moveable components and actuation mechanisms may be used. Other micro-mechanical devices such as chemical sensors may have no physical/mechanical actuation means, and provide only a passive readout. Temperature control MEMS structures may have no moving parts or electrical parts, but are formed in semiconductor or other materials and allow movement of fluids.

MEMS structure 310 can be formed by processing steps used in the fabrication of MEMS components with silicon, silicon dioxide, silica glasses, nitrides, thin-film metals or other materials described herein. Such processing includes thin film deposition, patterning and etching techniques. For example, CMOS processing is used.

Deposition techniques include both the physical deposition of material on a substrate and growth of a material on a substrate as are known in the art. Thin films created by such deposition techniques are generally on the order of 25 microns or less in thickness and typically 10 microns or less. Patterning techniques include lithographic patterning, printing or other form of pattern transfer, including mechanical pattern transfer, as are known in the art. Etching techniques include both chemical “wet” etching, plasma “dry” etching and laser etching as are known in the art. The term “micro-machining” is often used to refer to these semiconductor style processes utilized to fabricate micro-mechanical devices. Further, micro-machining includes both “bulk” micro-machining and “surface” micro-machining. Bulk micro-machining is the process of fabricating mechanical structures by etching the bulk of a substrate. Surface micro-machining is the process of fabricating mechanical structures on the surface of a substrate by deposition, patterning and etching layers of different materials and using other semiconductor style processes.

An exemplary fabrication sequence for making a MEMS switch such as the MEMS structure 310 begins with the deposition and patterning of a first metal layer (e.g. chrome-gold) to define gate and contact electrodes on the monocrystalline silicon substrate 302. A sacrificial metal layer (e.g. copper) approximately 2 microns thick is then deposited. The sacrificial metal layer is patterned in 2 steps. In the first step, the sacrificial layer is partially etched to define contact tips for a moveable beam. In the second etch step, the sacrificial layer is etched all the way down to the source contact metal to define beam supports. Subsequently, photo-resist is spun on top of the sacrificial layer and patterned to define the mask for the beam structure. The beam consists of a 2 micron thick layer of nickel on top of a 200 nm thick layer of gold. Both these layers can be formed either by electroplating or by electroless plating. The gold layer serves as contact material with the gold contact pads when the switch closes. Finally, the sacrificial layer is removed by a suitable wet etching process to release the free-standing beam. Other techniques for forming a same or different MEMS structure 310 may be used, such as techniques for etching, patterning and depositing silicon, oxides and compound semiconductor materials.

Additional MEMS structures and/or semiconductor devices can be formed on the monocrystalline silicon substrate 302. For example, a CMOS transistor or other devices discussed herein are formed adjacent to the MEMS structure 310 as discussed above.

After forming any structures or devices on the monocrystalline silicon or other substrate 302, the semiconductor components 306 on the monocrystalline compound semiconductor layer 304 are formed using the techniques described in detail above. Any insulating material and any other layers that may have been formed or deposited during the processing of the MEMS structure 310 are removed from the surface of region 312 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 312 and is reacted with the oxidized surface to form a first template layer. In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition, the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 312 to form an amorphous layer of silicon oxide on the region 312 and at the interface between silicon substrate 302 and the monocrystalline oxide. These layers may be subject to an annealing process as described above in connection with FIG. 3 to form a single amorphous accommodating layer. Other techniques for forming the amorphous accommodating layer described above may be used.

In accordance with an embodiment, the step of depositing the monocrystalline oxide layer is terminated by depositing a second template layer, which can be 1-10 monolayers of titanium, barium, barium and oxygen, or titanium and oxygen. The layer 304 of a monocrystalline compound semiconductor material is then deposited overlying the second template layer by a process of molecular beam epitaxy. The deposition of the monocrystalline compound semiconductor layer 304 is initiated by depositing a layer of arsenic onto the template. This initial step is followed by depositing gallium and arsenic to form monocrystalline gallium arsenide or depositing other compound semiconductor materials. Alternatively, strontium can be substituted for barium in the above example.

As discussed above for FIGS. 26-37, additional layers may be formed over the MEMS structure 310 as the monocrystalline compound semiconductor layer 304 and semiconductor device 306 are formed. The metallic conductor indicated by line 308 is formed using deposition of metal traces or other techniques as described above. In alternative embodiments, the MEMS structure 310 is formed through or within the monocrystalline compound semiconductor layer 304, or the semiconductor device 306 is formed first and any layers above the silicon substrate 302 are later removed for forming the MEMS structure 310. In yet other alternative embodiments, different materials and associated layer structures are used. The MEMS structure 310 may be positioned as shown adjacent to or alternatively below the semiconductor device 306. Additional layers of monocrytalline material and associated amorphous layers may also be provided.

Various combinations of MEMS structure 310 and semiconductor devices 306 can be used. In one embodiment, an optical switch MEMS structure 310 either directs, turns off or selectively splits light from a diode or laser diode. The optical switch comprises a moveable mirrored surface or lens with grating positioned in a light waveguide formed with a laser diode as discussed above. In response to actuation of the optical switch by rotating or changing an angle of the MEMS structure, the light is directed to one or more optical detectors or waveguides or split to two or more optical detectors or waveguides.

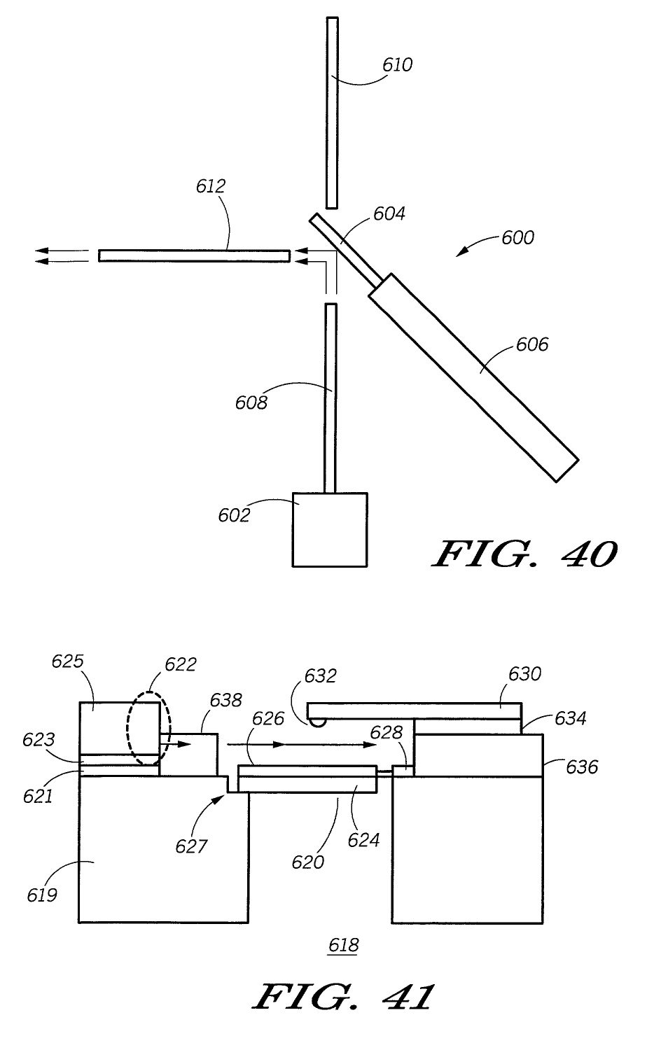

FIGS. 39 and 40 illustrate integrating a MEMS switch 600 with an optical source 602 on a monolithic device 617. The optical source 602 comprises a VCSEL, laser diode or other light emitting semiconductor device. For example, the optical source discussed above and illustrated in FIGS. 31-37 is formed.

The MEMS switch 600 comprises a mirror 604 and an actuator 606. The mirror 604 comprises a mirror formed as discussed above, such as alternating layers of gallium arsenide and aluminum gallium arsenide or other materials, polished silicon or other light reflective surface. The actuator 606 comprises electrodes and other MEMS structure for moving the mirror 604 between the two positions shown in FIGS. 39 and 40. For example, the actuator 606 comprises a chamber with electrodes and a piston with electrodes. The piston moves within the chamber as a function of voltages applied to the electrodes. The actuator 606 moves the mirror into and out of a path of propagation of the light emitted by the optical source 602. The optical source 602 provides light to an integrated waveguide 608.

Waveguides 608, 610 and 612 optically connect the optical source 602 with other devices, such as transistors, diodes, fiber optical cable, splitters, other waveguides, lenses or combinations thereof. The waveguides 608, 610 and 612 comprise the material and structures discussed above, but other light guiding structures or materials can be used. Collimating or other lenses can be formed at the ends of one or more of the waveguides 608, 610 and 612. Lenses may prevent loss of light during propagation through air or other gases between waveguides 608, 610 and 612.

As illustrated in FIGS. 39 and 40, the position of the mirror 604 controls the propagation of light. In the position illustrated in FIG. 39, the mirror 604 is positioned away from light output from the waveguide 608. Light emitted from waveguide 608 is incident on waveguide 610. No or little light is incident on waveguide 612. In the position illustrated in FIG. 40, the mirror 604 is positioned in a path of propagation of light output by the waveguide 608. The mirror 604 is positioned or angled to reflect light towards the waveguide 612. In one embodiment, the mirror 604 prevents light from propagating to the waveguide 610. In another embodiment, the mirror 604 also passes light to the waveguide 610 in the position shown in FIG. 40.

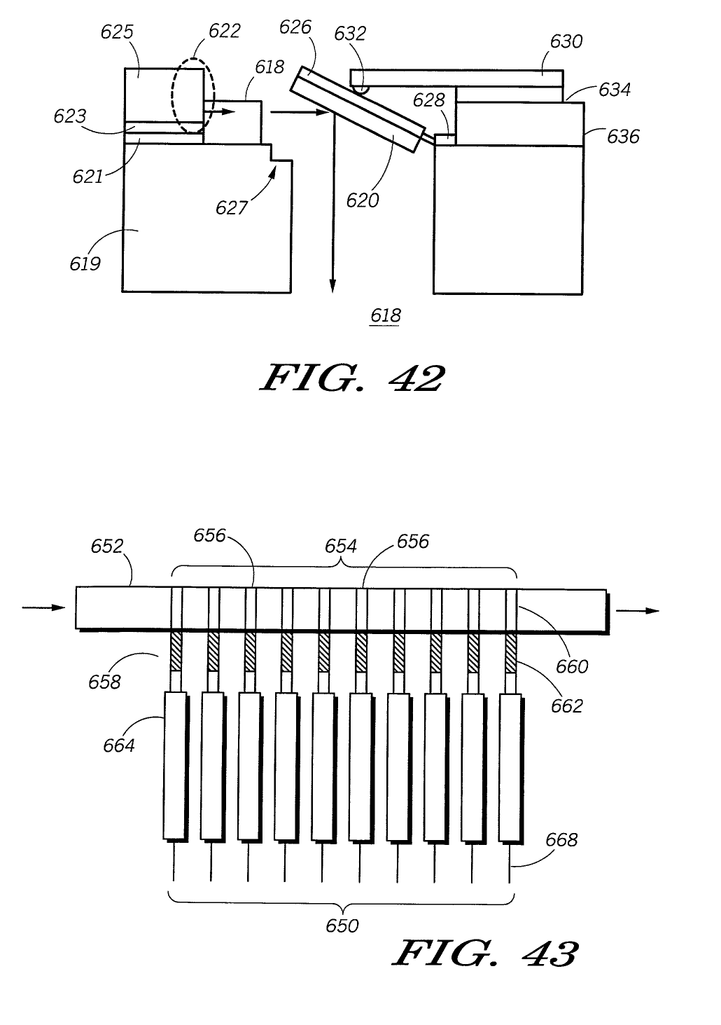

FIGS. 41 and 42 illustrate another MEMS switch 620 integrated with an optical source 622 on a monolithic device 618. The monolithic device 618 comprises a monocrystalline silicon wafer 619. An amorphous intermediate layer 621 and an accommodating buffer layer 623, similar to those previously described, are formed over wafer 619. Layers 621 and 623 may be subject to an annealing process as described above in connection with FIG. 3 to form a single amorphous accommodating layer. A compound semiconductor layer or layers 625 are formed on the accommodating buffer layer 623.

The optical source 622 is formed in the compound semiconductor layer 625 as discussed above. The optical source 622 comprises an edge emitting laser diode or other light generating semiconductor device.

The MEMS switch 620 comprises a movable mirror 624 on a hinged device, a cantilever, a membrane or a combination thereof A metal contact 626 is deposited on top or beneath the moveable mirror 624. A control line contact 628 electrically connects with the metal contact 626. A beam 630 formed of any of the materials discussed herein includes a metal or conductive area 632. In one embodiment, an insulating material coats the metal contact 626 or the conductive area 632 to prevent a direct short-circuit from contact of these two conductors. Another layer of insulating material 634 prevents contact from conductive regions or metal layers of the beam 630 and an optical waveguide 636. A stop 627 is formed or etched in the substrate 619 to limit rotation of the mirror 624 away from the beam 630. Other MEMS switch structures or materials can be used.

Optical waveguides 636 and 638 are formed as discussed above on the monolithic device 618. With the MEMS switch 620 in the open position illustrated in FIG. 41, light generated by the optical source 622 is passed through sufficiently transparent gas or air from the waveguide 638 to the waveguide 636 or other device, such as a transistor, diode or fiber optic cable.

To reposition the MEMS switch 620, a voltage is applied across the conductive area 632 and the metal contact 626, causing an electrostatic force in the preferred embodiment. The mirror 624 moves to the position illustrated in FIG. 42. The light emitted from the waveguide 638 is re-directed or reflected through an opening in the silicon substrate 619. Alternately, an optical waveguide could be formed for receiving the reflected light. Other alternate embodiments include a fiber optic cable connection or a lens to collimate the emitted light.

FIGS. 43-45 illustrate a MEMS switch 650 integrated as a monolithic device with a waveguide 652 for passing light at selective wavelengths. The waveguide 652 comprises an optical waveguide formed as discussed above on a monolithic device. The waveguide 652 includes a selectable Bragg grating section 654. One or more slots 656 are periodically spaced as a function of wavelength(s). The Bragg grating section 654 is configured to selectably reject one or more wavelengths of incident light passing through the waveguide 652.

The MEMS switch 650 positions different sections of plungers 658 within the slots 656. The plungers 658 comprises one section 660 with a substantially same index of refraction as the waveguide 652 and at least another section 662 with a different index of refraction. The index of refraction of the section 662 is a function of the wavelength or wavelengths to be rejected by the Bragg grating section 654. The material forming or coating the section 662 determines the index of refraction. In one embodiment, the section 660 comprises a same or similar material as the waveguide 652 and the section 662 comprises a different material, such as a compound semiconductor material.

The plungers 658 moveably connect with actuators 664. The actuator 664 comprises electrodes and other MEMS structure for moving the plungers 658. The plungers 658 include a metal section 666 which extends into the MEMs actuator 664. The metal section 666 acts as a solenoid within the actuator 664. The metal section 666 is positioned as a function of a voltage applied on the control line 668.

The plungers 658 are positioned so that one of sections 660 and 662 are within the slots 656. When the sections 660 are positioned in the slot 656 as illustrated in FIG. 43, no or little grating is provided. All or most incident wavelengths of light are passed through the waveguide. When the sections 662 are positioned in the slot 656 as illustrated in FIG. 45, grating is provided. Incident light can consist of multiple wavelengths of light, λ₁, λ₂, . . . λₙ. To selectively reject wavelength λ₂, the plungers 658 are positioned so that sections 662 are within the propagation path of the light in the waveguide 652. The Bragg grating is spaced such that light corresponding to λ₂ is reflected. Other wavelengths of the light are passed. The wavelength for rejection is selected as a function of the number of sections 662 and the properties of those sections 662 positioned within the path of propagation. FIG. 43 illustrates all of the sections 660 in the waveguide 652, and FIG. 45 illustrates all of the sections 662 in the waveguide 652, but combinations of sections 660, 662 in the waveguide 652 can be used.

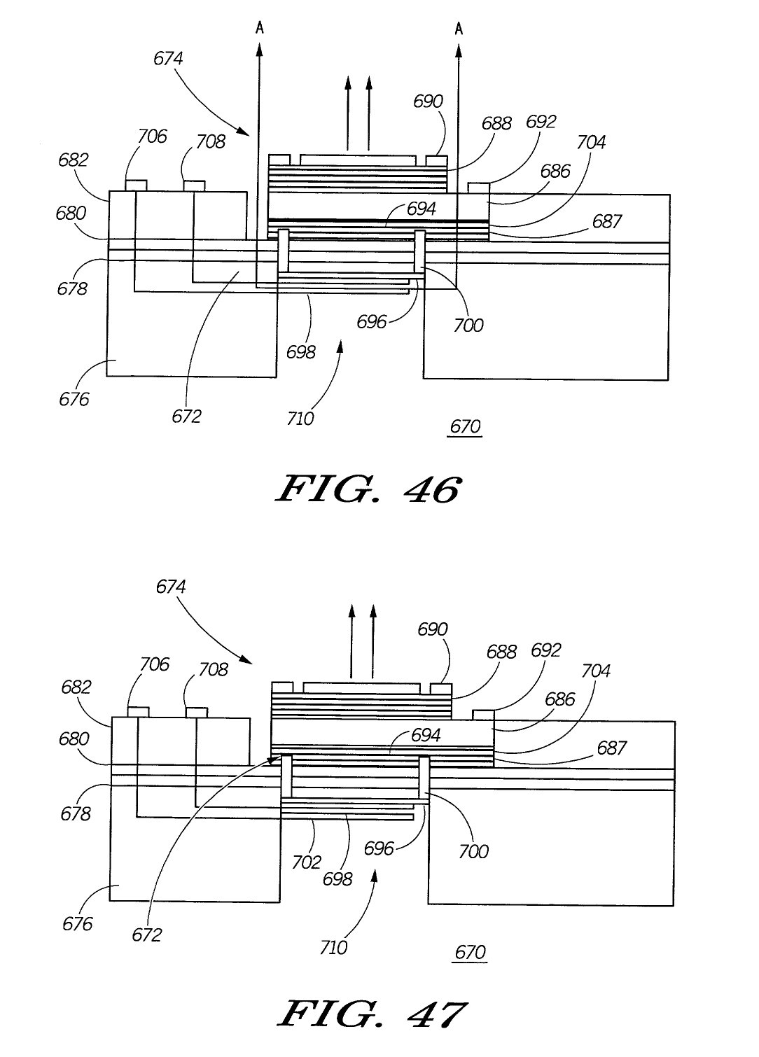

FIGS. 46-48 illustrate a tunable VCSEL on a monolithic device 670. A MEMS switch 672 is integrated with a VCSEL 674 on the monolithic device 670.

The monolithic device 670 comprises a monocrystalline silicon wafer 676. An amorphous intermediate layer 678 and an accommodating buffer layer 680, similar to those previously described, are formed over wafer 676. Layers 678 and 680 may be subject to an annealing process as described above in connection with FIG. 3 to form a single amorphous accommodating layer. A compound semiconductor layer or layers 682 are formed on the accommodating buffer layer 680.

The VCSEL 674 comprises a semiconductor laser formed in one or more semiconductor layers as discussed above and illustrated in FIGS. 31-37. For example, the VCSEL 674 comprises: a lower region 684 of undoped alternating layers of GaAs and AlGaAs, an active region 686 of InP or InGaAsP, and an upper region 688 of p-doped alternating layers of GaAs and AlGaAs. Electrical contacts 690 and 692 are deposited on the VCSEL 674 for biasing and generation of light. Other light generating semiconductor devices or VCSEL structures can be used.

Some of the layers of the lower region 684 are formed as part of the MEMS switch 672. The MEMS switch 672 comprises one or more movable layers 694 associated with the lower region 684, a flexible membrane 696, a metal layer 698, one or more layers 700 of silicon, semiconductor or other material between the movable layers 694 and flexible membrane 696, and a metal layer 702. In alternative embodiments, the MEMS switch comprises an actuator and plunder. The movable layers 694 are formed on the layers 700 as discussed above, such as by forming an accommodating buffer layer on silicon and growing or depositing the movable layers 694 on the buffer layer. The number of layers in the lower region 684 includes the movable layers 694 and other layers 704 not part of the MEMS switch 672. The number of layers 694 and 704 comprise approximately the number of layers used for a lower mirror region of a VCSEL.

Metal contacts 706 and 708 are deposited and electrically connect with the metal layers 698 and 702. The flexible membrane 696 adjusts position as a function of voltage applied to the metal contacts 706 and 708. In a rest position, the flexible membrane 696 positions the layers 694 against the layers 704. By applying voltage, the metal layer 698 is forced towards the metal layer 702. The flexible membrane 696 moves, providing a gap between the mirror layers 694 and 704. Alternatively, the rest position of the flexible membrane 696 has a gap between the layers 694 and 704 of the lower region 684.

Moving the layer 694 tunes the VCSEL 674. The wavelength of light output by the VCSEL 674 is adjusted by the MEMS switch 672. FIG. 46 illustrates the MEMS switch 672 positioned so that the VCSEL 674 operates at a first wavelength. FIG. 47 illustrates the MEMS switch 672 set so that the VCSEL 674 operates at a different wavelength as a function of the gap between the layers 694 and 704.

In one embodiment, an open region 710 is etched through the silicon substrate 676 for forming the MEMS switch 672. After forming the MEMS switch 672 or the VCSEL 674, a plug is formed or placed within the open region 710. The enclosed area is then evacuated or backfilled with an inert gas. In alternative embodiments, the MEMS switch 672 and VCSEL 674 are formed without the open region 710 through the substrate 676. The area for operation of the flexible membrane 696 can be evacuated or backfilled with an inert gas.

FIG. 48 illustrates a view of section A-A′ in FIG. 46. The moveable mirror assembly of the MEMS switch 672 is shown. The flexible membrane 696 is formed from the silicon substrate 676 or another material. The metal layer 698 is deposited as a thin ring and attached to the contact 708 by the conductive bridge 712. In one embodiment, the metal layer 698 comprises a series of very fine concentric rings connected at one or more points to provide electrical continuity. The movable mirror layers 694 are indicated by a long-dashed line and the lower, fixed mirror layers 704 are indicated by a short-dashed line. The diameters and shape of the layers 694 and 704 are the same or similar. In alternative embodiments, the layers 694 are different shape or size than the layers 704.

MEMS devices can be integrated for other purposes. In another embodiment, a low loss switch MEMS structure 310 electrically connects with a transistor, amplifier, a dielectric resonator or combinations thereof. The switch can operatively connect resistor, capacitor, inductor or other integrated or non-integrated circuitry for tuning or controlling operation of the transistor, amplifier or other semiconductor device 306. For example, the switch controls a tunable oscillator circuit or a tunable filter component formed in part as the semiconductor device 306. In alternative embodiments, the MEMS structure 310 comprises a variable capacitor, resistor or inductor for tuning the tunable oscillator circuit or tunable filter component formed on the monocrystalline compound semiconductor layer 304. Signals at different frequencies are generated by the tunable oscillator or dielectric resonator as a function of the signal from the MEMS switch or variable capacitance. Different filter bandwidths and/or other characteristics are selected as a function of the MEMS switch or variable capacitance. As a result, an integrated low loss and inexpensive tunable oscillator or filter is provided.

In yet another embodiment, the MEMS structure 310 comprises a switch and electrically connects with a transceiver including at least the semiconductor device 306. For example, the switch can be connected to tune a resonator or oscillator for selecting frequencies to be received or transmitted. As another example, the switch selects between connecting an antenna or other transducer between transmit and receive components of the transceiver. Using this combination of components, an entire radio or other transceiver is integrated into a monolithic device.

Other combinations of MEMS structure 310 and active or passive semiconductor devices 306 can be used. For example, MEMS control of an integrated dielectric resonator is provided. A plate is moved within a radio frequency field to tune the frequency used for an oscillator. As another example, MEMS structure is used to sense pressure, temperature, motion or other environmental characteristics and semiconductor devices process the sensed information. A flexible membrane, cantilever or other moveable device is used to detect the environmental characteristics. As yet another example, a MEMS structure provides phase shifting in a circuit including a semiconductor device. A MEMS switch selects a length of a connection or transmit line or selects from multiple signals with different phases to shift phase. As another example, a MEMS structure controls an antenna used by a semiconductor device. A MEMS switch or variable capacitor controls an amplifier semiconductor device to control the strength of a transmitted or received antenna signal.

Forming multiple MEMS structures 310 and/or semiconductor devices 306 allow the integration of complex circuitry with low loss, efficiency and reduced cost and space requirements as compared to non-monolithic implementation. Some MEMS structures and semiconductor devices are optimized as a function of the material used, such as monocrystalline silicon or monocrystalline compound semiconductor material. By providing two or more types of material in a monolithic device, integration is maximized. Any various combinations of MEMS structure and semiconductor devices now known or later developed may be used.

FIG. 49 illustrates a monolithic defvice 369 that includes another embodiment of a MEMS switch 316. The MEMS switch 316 is formed in the monocrystalline silicon substrate 302. The MEMS switch 316 comprises a moveable piston or actuator 318, biasing device or spring 320, a shaft 322 and at least two contacts 324, 326. The actuator 318 moves between the contacts 324, 326 on the shaft 322. A chamber 310 allowing movement of the actuator 318 and operation of the spring 320 is formed. The spring 320 applies a downward or upward force to predispose the actuator 318 relative to one of the contacts 324, 326. Metal or conductive plated vias 328 connect to the shaft 322 and actuator 318 and the contacts 324, 326. The contacts 324, 326 are plated or conductive to transmit an electrical signal. Transmission lines 330 comprise a conductive material and are deposited on the monocrystalline compound semiconductor layer 304 of the monolithic device 369.

A DC current is either applied or not applied across the actuator 318 and one of the contacts 324, 326. The DC current counteracts the force from the spring 320 to move the actuator 318 away from one of the contacts 324 or 326 and into contact with the other contact 326 or 324. One of the transmission lines 330 provides the appropriate DC voltage differential to one of the contacts 324, 326.

AC signals are transmitted through the switch 316. The switch 316 passes the AC signals from one of the transmission lines 330, such as the one associated with the shaft 322, to the selected contact 324, 326. The switch 316 may block any transmission by positioning the actuator 318 out of contact with either of the contacts 324, 326 (i.e., balance the spring force with the DC potential force). At least one of the transmission lines connects directly or indirectly with the semiconductor device 306.

In alternative embodiments, an on/off switch or switches with three or more contacts may be formed. The switch can comprise a predisposed beam or cantilever without any spring structure, or a flexible membrane allowing contact or providing separation between two electrodes. Rotary or other moveable structures may be used.

FIG. 50 illustrates another monolithic device 359 that includes one embodiment of a MEMS variable capacitor 340. The MEMS variable capacitor 340 is formed in the monocrystalline silicon substrate 302. The MEMS variable capacitor 340 comprises a chamber 348 with a moveable plunger or actuator 342, biasing device or spring 344, a shaft 346, first plates 350 connected with the actuator 342 and second plates 352 connected with an electrical contact 354. The number, shape and size of the first and second plates 350, 352 may vary or be the same and are a function of the desired capacitance range. The first and second plates 350, 352 electrically connect to transmission lines 356 through vias 358. The actuator 342, shaft 346 and vias 358 comprise conductive material or are plated. Transmission lines 356 comprise a conductive material and are deposited on the monocrystalline compound semiconductor layer 304 or on the monocrystalline silicon substrate 302 of the monolithic device 359.

In one embodiment, the actuator 342 moves horizontally to increase or decrease an area of overlap between the first and second plates 350, 352, resulting in different capacitance. In another embodiment, the actuator 342 moves vertically to increase or decrease the proximity of adjacent first and second plates 350, 352, resulting in different capacitance. In yet another embodiment, the first and second plates 350, 352 are fixedly mounted in a parallel arrangement and the actuator 342 electrically contacts the first plates 352. By moving the actuator 342 vertically, the number of first plates 350 electrically connected with the actuator 342 changes, resulting in a different capacitive area and capacitance. The chamber 348 allows movement of the actuator 342 and/or first plates 350 and operation of the spring 346. The spring 344 applies a downward, upward or horizontal force to predispose the actuator 342 to one position, such as associated with the maximum or minimum capacitance.

A DC current is either applied or not applied across the actuator 342 and ground or another electrode adjacent the actuator 342. The DC current counteracts the force from the spring 344 to move the actuator 342.

In alternative embodiments, a flexible membrane positions conductive plates closer or further apart to vary the capacitance in response to an applied DC voltage. Other variable capacitance MEMS structures may be used. The MEMS variable capacitor 340 electrically connects with a semiconductor device in the monocrystalline compound semiconductor layer 304.

MEMS structures can also control the temperature of a chip, semiconductor device, die or monolithic integrated circuit. Heating or cooling is provided by the MEMS structure. The MEMS structure is formed in the monocrystalline silicon substrate, the monocrystalline compound semiconductor layer, amorphous intermediate layer, accommodating buffer layer or combinations thereof. The MEMS structure provides more efficient heat or cold transfer to or from other components, such as semiconductor devices in the monocrystalline silicon substrate, the monocrystalline compound semiconductor layer, amorphous intermediate layer, accommodating buffer layer or combinations thereof. For example, a MEMS structure in the monocrystalline silicon substrate transfers heat away from a MESFET, PHEMT, HBT, VCSELS, other transistor, laser diode or other semiconductor device in the monocrystalline compound semiconductor layer. Using both a monocrystalline silicon substrate and a monocrystalline compound semiconductor layer, an integrated temperature control for high frequency semiconductor devices is provided. This temperature control integration may allow operation of semiconductor devices (e.g. VCSEL) at optimum temperatures, increase temperature control efficiency, reduce space requirements and reduce manufacturing costs or complication.

MEMS structures for transferring heat or cold comprise tubes or channels positioned with one portion near a semiconductor device and another portion away from the semiconductor device. A fluid, such as a liquid or gas, is transported to or away from the semiconductor device and from or to a heat sink, heat spreader, surface or other heat radiator.

FIG. 51 illustrates a MEMS temperature control structure 370 integrated with a semiconductor device 372 in a monolithic chip 374. The monolithic chip 374 is mounted to a circuit board 376 on mounting supports 378. The mounting supports 378 comprise solder or other conductive adhesive or material extending from the circuit board 376, transmission lines or other devices. The mounting supports 378 are used for mounting the monolithic chip 374 to the circuit board 376.

The monolithic chip 374 includes the monocrystalline silicon substrate 302, the monocrystalline compound semiconductor layer 304 and a thermal conductive layer 380. The monocrystalline silicon substrate 302 and the monocrystalline compound semiconductor layer 304 are formed as discussed above, including alternative materials, layer structures and processes.

The thermal conductive layer 380 comprises a heat sink, heat spreader, or other heat radiator. In one embodiment, the thermal conductive layer 380 comprises a heat conductive ceramic, such as alumina, beryllium oxide, aluminum oxide, diamond or other ceramics, formed as a plate with fins 382. Other thermally conductive materials, such as metal or plastic, may be used. A metal can be deposited over a part or all of the conductive ceramic. Different structures, such as metallic strips, a lattice of fins without the plate, a plate or electrode without fins or other structures, may be used. In alternative embodiments, no thermal conductive layer is provided.

Pressure, heat, adhesives, deposition or other processes are used to apply the thermal conductive layer 380 to the monolithic chip 374. Pins or other structures may be used to align the thermal conductive layer 380 on the monolithic chip 374.

The monolithic chip 374 is oriented with the active semiconductor device 372 positioned downward and/or closest to the circuit board 376. Since heat rises and the circuit board may prevent heat transfer, the position of the monolithic chip 374 more efficiently provides thermal transfer.

The semiconductor device 372 comprises a transistor, amplifier, diode, laser diode or other semiconductor device discussed herein. The semiconductor device 372 is formed in the monocrystalline compound semiconductor layer 304.

Also within the monocrystalline compound semiconductor layer 304 is a thermal via 384. The thermal via 384 comprises a different material than the monocrystalline compound semiconductor layer 304: a liquid, a gas (e.g., air) or other substance for pulling heat from the semiconductor device 372. The thermal via 384 is formed by depositing material prior to depositing the monocrystalline compound. The material comprises the thermal via 384 or is etched away to form the thermal via 384. The thermal via 384 pulls heat from the semiconductor device 372 within the monocrystalline compound semiconductor layer 304 adjacent to the interface with the monocrystalline silicon substrate 302 or amorphous or buffer layers (not shown). The monocrystalline compound semiconductor layer 304 conducts heat poorly as compared to the thermal via 384. In alternative embodiments, the thermal via 384 is formed in the amorphous or buffer layers or the monocrystalline silicon substrate 302. In yet other alternative embodiments, the thermal via 384 is not provided.

The MEMS structure 370 comprises one or more tubes 386 and corresponding reservoirs 388 and 390. The tubes 386 are sized and shaped to act as passive heat pipes. The tubes 386 are formed using the MEMS techniques discussed above, such as techniques for forming a via within silicon, and extend from one reservoir 388 to another reservoir 390. In alternative embodiments, the tubes 386 interconnect, traverse the monocrystalline silicon substrate 302 circuitously, or have varying dimensions.

The reservoirs 388 and 390 are formed at each end of the tubes 386 or are connected with the tubes 386 at other positions. Any of the MEMS techniques may be used to form the reservoirs 388 and 390, such as applying for a particular time period a chemical that etches silicon at the end of each tube 386. The reservoirs 388 and 390 are formed in the monocrystalline silicon substrate 302, the monocrystalline compound semiconductor layer 304, the amorphous layer, the buffer layer or the thermal conductive layer 380. As illustrated in FIG. 51, reservoirs 388 adjacent the semiconductor device 372 are formed in the monocrystalline silicon substrate 302 at an interface with the monocrystalline compound semiconductor layer 304, and reservoirs 390 are formed in the thermal conductive layer 380 for the transfer of heat. Tubes 386 without reservoirs 388 or 390 at one or both ends of the tubes 386 can be used. Likewise, reservoirs 388 or 390 without tubes 386 can be used.

The tubes 386 conduct thermal energy more efficiently than the monocrystalline silicon substrate 302. The tubes 386 and reservoirs 388 and 390 are evacuated of undesired material. A small amount, as compared to the volume of the tubes 386 and reservoirs 388 and 390, of thermally conductive fluid (liquid or gas) is inserted into the tubes 386 or reservoirs 388 and 390. For example, de-ionized water or methanol is inserted into each tube 386 or an associated reservoir 388, 390. The tubes 386 and reservoirs 388 and 390 are hermetically sealed, such as positioning and attaching the thermally conductive layer 380, placing a plug, such as growing an oxide layer or applying a spin coated layer, in the reservoirs 388, 390 or closing a via. Gravity positions the thermally conductive fluid in the lower reservoirs 388. As the fluid is heated by proximity to the thermal via 384 and/or the semiconductor device 372, the fluid evaporates. The heated evaporated fluid rises through the tubes 386 to the upper reservoirs 390 and condenses as heat is transferred to the thermally conductive layer 380. The cooled, condensed fluid returns through the tubes 386.

Other passive MEMS structures may be used. FIG. 52 shows reservoirs 402 adjacent a different thermally conductive layer 404. The tubes 386, lower reservoirs 388, monocrystalline compound semiconductor layer 304, semiconductor device 372, monocrystalline silicon substrate 302 and alternative are as discussed above.

The reservoirs 402 are formed as discussed above, such as a timed etch with or without patterned etching blocks formed in the monocrystalline silicon substrate 302.

The reservoirs 402 are formed in the monocrystalline silicon substrate 302.

The reservoirs 402 are sealed with plugs 406. The plugs 406 comprise metal, ceramic, oxide or other material deposited, coated or grown to seal the reservoirs 402.

The thermally conductive layer 404 comprises one or more ridges 408, but fins or other structure increasing the surface area of the monocrystalline substrate 302 can be used. In one embodiment, the ridges 408 comprise deposited metallic structures passing over or near the plugs 406. In another embodiment, the monocrystalline silicon substrate 302 is etched to form the ridges 408. A metal layer can be deposited over the etched surface of the monocrystalline silicon substrate 302, including the ridges 408. Depositing metal on the etched surface may be done in a same or different step as forming the plugs 406.

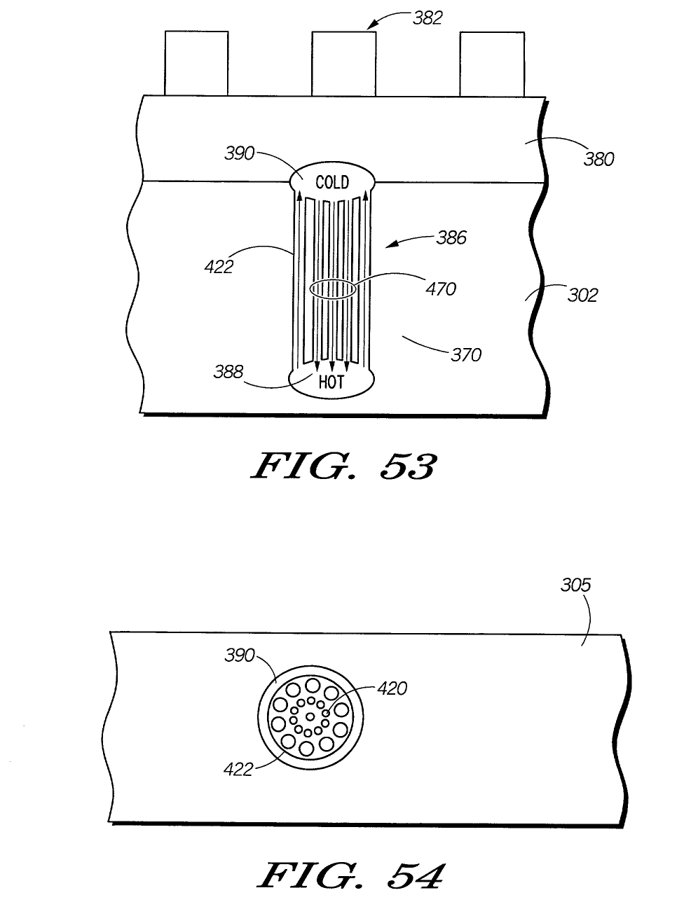

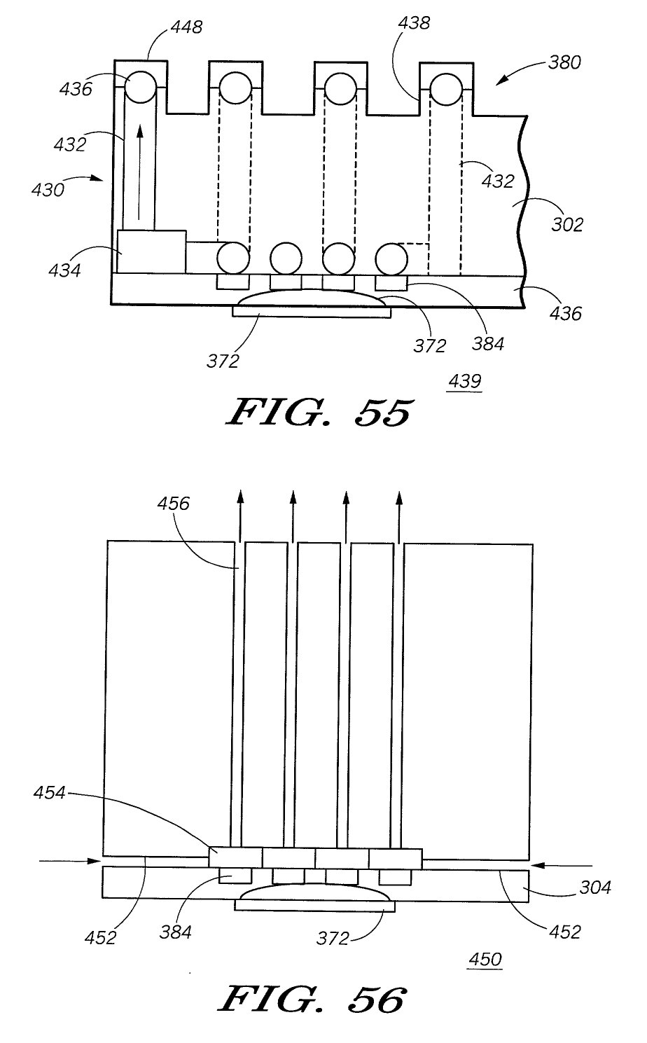

FIGS. 53 and 54 illustrate forming the tubes 386 as more complex passive MEMS structures. Two or more types of tubes 420, 422 connect between the reservoirs 388 and 390. One type of tube 422 is formed to allow vaporized fluid to flow from the hotter reservoir 388 to the cooler reservoir 390. For example, this type of tube 422 has a larger diameter than the other type of tube 420. The other type of tube 420 has a smaller diameter, such as in the order of hundreds of microns. The smaller tubes 420 are sized as a function of the fluid to induce capillary action to the condensed fluid in the colder reservoir 390.

Vaporized fluid carrying thermal energy rises through the larger tubes 422 to the cooler reservoir 390. The thermal energy is released as the fluid condenses in the cooler reservoir 390. The condensed fluid travels through the smaller tubes 420 due to capillary action and/or gravity to the warmer reservoir 388. Capillary action allows thermal transfer in low or no gravity environments.

In one embodiment, a plurality of both types of tubes 420, 422 are provided, such as a ring of larger tubes 422 positioned outward from a ring of smaller tubes 420. The smaller tubes 420 are positioned in the reservoir 390 where condensed fluid is likely to pool. The larger tubes 422 are positioned in the reservoir 390 where condensed fluid is unlikely to block flow of the vaporized fluid. Different numbers of tubes 420, 422, such as one or more, can be used in any relative position.

FIG. 55 illustrates a monolithic device 439 that includes an active MEMS temperature control structure 430 in the monocrystalline silicon substrate 302. The MEMS temperature control structure 430 comprises tubes 432 and a pump 434. The tubes 432 comprise one or more enclosed circuits that pass through the pump 434. The tubes 432 are positioned adjacent the thermal vias 384 or the semiconductor device 372. The tubes 432 pass through the monocrystalline silicon substrate 302 to the thermal conductor layer 380. The tubes 432 complete the circuit by returning to the position adjacent the thermal vias 384 or the semiconductor device 372. In one embodiment, each tube 432 extends along a length adjacent the semiconductor device 372 and the thermal conductive layer 380 as represented by 436 to maximize thermal transfer. One or more separate tube circuits can be provided. Multiple tubes 432 can interconnect, forming multiple interconnected circuits for transferring heat from the semiconductor device 372 to the thermal conductive layer 380.

The pump 434 comprises a MEMS structure, such as a diaphragm, piston, vane or gear, designed to force displacement of fluid. One or more electrical connections and associated voltage may be provided to actuate the pump 434. For example, an alternating current is applied across two electrodes, one electrode on a diaphragm connected with the tube 432 and another electrode across a gap from the diaphragm. The diaphragm moves cyclically in response to the alternating current. A directional valve allows fluid to flow in one direction in the tube 432 in response to movement of the diaphragm. Other pump MEMS structures may be used, such as pumps applying a centrifugal force to the fluid in the tubes 432. Yet another embodiment uses electromagnetic force to move metal beads within the fluid. The moving beads force the fluid to move.

One pump 434 is provided for each tube circuit, but a plurality of pumps 434 can be used for each tube circuit. As illustrated in FIG. 55, two or more tube circuits may interconnect and share a single pump 434 or bank of pumps. The pump 434 is positioned at any location along the tube circuit. In one embodiment, the pump 434 is positioned adjacent to and formed before deposition of the monocrystalline compound semiconductor layer 304, which is thereby included in the monolithic device 439. In an alternative embodiment, the pump 434 is formed on the monocrystalline silicon substrate 302 at an edge portion or adjacent the thermally conductive layer 380.

The thermally conductive layer 380 comprises one or more radiator fins 438 etched from the monocrystalline silicon substrate 302. The tubes 432 extend within the radiator fins 438. Ceramic, metal, silicon, oxide or other caps 440 are positioned over the radiator fins 438 to enclose or form the tubes 432. The vias to form the tubes 432 are etched and the tube circuits filled or partially filled with thermally conductive fluid prior to forming the caps 440.

The pump 434 circulates the fluid in the tubes 432. The fluid adjacent the semiconductor device 372 is heated and pumped towards the thermally conductive layer 380. Within the tubes 432 in the monocrystalline silicon substrate 302 and the thermally conductive layer 380, the heat is radiated and the fluid cools. The cooled fluid is continuously or periodically pumped back to be heated again.

In alternative embodiments, the pump 434 comprises a compressor. A gaseous fluid is compressed for heat transfer. This embodiment acts as an air conditioner system. In yet other alternative embodiments, MEMS reversing valves or switches are provided and the tube circuit acts as a heat pump using a compressor. Either of heating or cooling is provided.

FIG. 56 illustrates another active monolithic MEMS temperature control structure 450. The MEMS temperature control structure 450 comprises one or more air inlets 452, one or more air pumps 454 and one or more air outlets 456. The air inlets 452 comprise one or more tubes of any dimension and shape. The air inlets 452 are etched as vias in the monocrystalline silicon substrate 302, but may be formed in the monocrystalline compound semiconductor layer 304 of the monolithic MEMS control structure 450, amorphous layer, buffer layer or combinations thereof. In one embodiment, the air inlets 452 are formed and covered prior to forming the monocrystalline compound semiconductor layer 304. The air inlets 452 fluidly connect the pumps 454 to a source of air, such as the environment adjacent a chip. For example, the air inlets 452 end at an edge surface of the chip.

The pumps 454 comprise one or more of the MEMS pump structures discussed above. In one embodiment, piston or diaphragm MEMS pumps are used to efficiently move gaseous air. The pumps 454 connect with one or more of the air inlets 452, drawing air from the air inlets 452. The pumps 454 and/or the air inlets 452 pass over or along the thermal vias 384 or the semiconductor device 372.

The air outlets 456 comprise one or more tubes of any dimension or shape. The air outlets 456 are etched as vias in the monocrystalline silicon substrate 302, but may be formed in the monocrystalline compound semiconductor layer 304, buffer layer, amorphous layer or combinations thereof. The air outlets 456 fluidly connect the pumps 454 to the environment or a chamber. For example, the air outlets 456 end at an edge surface of a chip. In alternative embodiments, the air outlets 456 can pass over the thermal vias 384 or semiconductor device 372 instead of or in addition to the pumps 454 and/or air inlets 452.

FIG. 57 illustrates the active MEMS temperature control structure 450 of FIG. 56 having a different configuration of the air inlets 452. The air inlets 452 extend from the pumps 454 in the monocrystalline silicon substrate 302 through the monocrystalline compound semiconductor layer 304. The air inlets 452 are ion etched entirely or in part after formation of the monocrystalline compound semiconductor layer 304. Other MEMS techniques may be used to form the air inlets 452. A portion of the air inlets 452 can be formed prior to deposition of the monocrystalline compound semiconductor layer 304, such as during formation of the pumps 454.

Air also flows to the air inlets 452 between the monocrystalline compound semiconductor layer 304 or outer surface of the chip 462 and the circuit board 376. Drawing air from adjacent the circuit board 376 and the semiconductor device 372 provides efficient cooling or heating. More area of the semiconductor device 372 is exposed to the fluid for cooling or heating.

In one embodiment, the circuit board 376 includes one or more apertures 460 for providing air to the air inlets 452. The apertures 460 can be positioned for maximizing air flow over the semiconductor device 372, such as being positioned below a center portion of the semiconductor device 372. In alternative embodiments, apertures 460 are aligned with the air inlets 452 or no apertures 460 are provided.

Any of the temperature controlling MEMS structures discussed above or other temperature control structures are used with any of various semiconductor devices. Some semiconductor devices are temperature sensitive, such as vertical cavity surface emitting lasers (VCSEL). VCSEL semiconductor devices can be formed with monocrystalline compound semiconductor materials as discussed above. The power output of VSCEL semiconductor devices decreases with increasing temperature. For example, 0.65 mW of power is provided at 20 degrees Celsius, but decreased to less than 0.1 mW at 85 degrees Celsius. One or more MEMS temperature control structures are integrated with the VCSEL semiconductor device to maintain a low temperature, providing higher power output.

The various embodiments for integration of MEMS structures discussed above may be used with any of the materials, layer or structures discussed herein. For example, while monocrystalline silicon substrate is used in the example embodiments above, other monocrystalline Group IV substrates can be used in addition or as an alternative. Other MEMS structures, MEMS processes, semiconductor devices or material characteristics can be used.

The MEMS structures shown in FIGS. 48-57 are formed as monolithic devices with two different layers of monocrystalline semiconductor material. The characteristics of one of these materials allows the formation of MEMS structures for interacting with semiconductor devices formed in the other of the materials. Such integration allows diversified circuits on one chip or device.

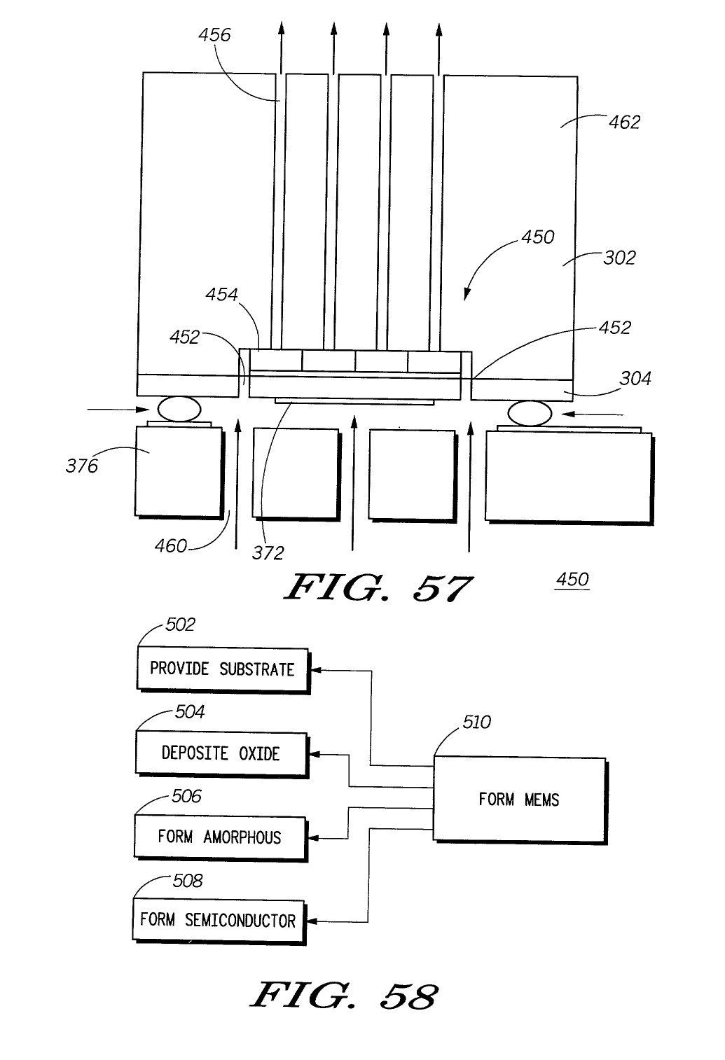

FIG. 58 illustrates a flow chart summarizing the process of one embodiment discussed above for fabricating the semiconductor structure. In act 502, a monocrystalline silicon substrate or other Group IV substrate is provided. A monocrystalline perovskite oxide film or other oxide is deposited overlying the monocrystalline silicon substrate in act 504. The film has a thickness less than a thickness of the material that would result in strain-induced defects. In act 506, an amorphous oxide interface layer or layer of other intermediate materials (e.g. amorphous oxide interface layer containing at least silicon and oxygen) is formed at an interface between the monocrystalline perovskite oxide film and the monocrystalline silicon substrate. A monocrystalline compound semiconductor layer is epitaxially or otherwise formed overlying the monocrystalline perovskite oxide film in act 508. In act 510, during, between or after the formation of the layers discussed above, a microelectromechanical structure is formed in at least one of the monocrystalline silicon substrate, the amorphous oxide interface layer, the monocrystalline perovskite oxide film and the monocrystalline compound semiconductor material.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a microelectromechanical structure formed in at least one of the monocrystalline silicon substrate, the amorphous oxide material, the monocrystalline perovskite oxide material and the monocrystalline compound semiconductor material.

2. The semiconductor structure of claim 1 wherein the microelectromechanical structure comprises a switch.

3. The semiconductor structure of claim 1 wherein the microelectromechanical structure comprises a variable capacitance structure.

4. The semiconductor structure of claim 1 wherein the microelectromechanical structure comprises a moveable device.

5. The semiconductor structure of claim 1 wherein the microelectromechanical structure comprises a tube within the monocrystalline silicon substrate.

6. The semiconductor structure of claim 1 wherein the microelectromechanical structure comprises a pump.

7. The semiconductor structure of claim 1 wherein the microelectromechanical structure comprises a membrane.

8. The semiconductor structure of claim 1 further comprising a semiconductor component formed in the monocrystalline compound semiconductor material.

9. The semiconductor structure of claim 8 wherein the semiconductor component comprises a transistor.

10. The semiconductor structure of claim 8 wherein the semiconductor component comprises a tunable oscillator circuit.

11. The semiconductor structure of claim 8 wherein the semiconductor component comprises a tunable filter component.

12. The semiconductor structure of claim 8 wherein the semiconductor component comprises a transceiver component.

13. The semiconductor structure of claim 8 wherein the semiconductor component comprises a dielectric resonator.

14. The semiconductor structure of claim 8 wherein the semiconductor component comprises an amplifier.

15. The semiconductor structure of claim 8 wherein the semiconductor component comprises a diode.

16. The semiconductor structure of claim 8 wherein the semiconductor component comprises a laser diode.

17. The semiconductor structure of claim 1 wherein the microelectromechanical structure is formed in the monocrystalline silicon substrate.

18. The semiconductor structure of claim 1 wherein the microelectromechanical structure comprises a temperature control structure.

19. The semiconductor structure of claim 15 wherein the microelectromechanical structure comprises an optical switch.

20. The semiconductor structure of claim 9 wherein the microelectromechanical structure comprises a switch.

21. The semiconductor structure of claim 9 wherein the microelectromechanical structure comprises a variable capacitance structure.

22. The semiconductor structure of claim 14 wherein the microelectromechanical structure comprises a temperature control structure.

23. The semiconductor structure of claim 15 wherein the microelectromechanical structure comprises a temperature control structure.

24. The semiconductor structure of claim 12 wherein the microelectromechanical structure comprises a switch connected between transmit and receive components.

25. The semiconductor structure of claim 1 wherein the monocrystalline compound semiconductor material comprises gallium arsenide.

26. The semiconductor structure of claim 1 wherein the monocrystalline compound semiconductor material comprises indium phosphide.

27. A process for fabricating a semiconductor structure comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film; and
(e) forming a microelectromechanical structure in at least one of the monocrystalline silicon substrate, the amorphous oxide interface layer, the monocrystalline perovskite oxide film and the monocrystalline compound semiconductor material.

28. The process of claim 27 wherein (e) comprises forming a switch.

29. The process of claim 27 wherein (e) comprises forming a variable capacitance structure.

30. The process of claim 27 wherein (e) comprises forming a moveable device.

31. The process of claim 27 wherein (e) comprises forming a tube within the monocrystalline silicon substrate.

32. The process of claim 27 further comprising:
(f) forming a semiconductor component in the monocrystalline compound semiconductor material.

33. The process of claim 32 wherein (f) comprises forming a transistor.

34. The process of claim 32 wherein (f) comprises forming a transceiver component.

35. The process of claim 32 wherein (f) comprises forming a dielectric resonator.

36. The process of claim 32 wherein (f) comprises forming a diode.

37. The process of claim 27 wherein (e) comprises forming the microelectromechanical structure in the monocrystalline silicon substrate.

38. The process of claim 27 wherein (e) comprises forming a temperature control structure.

39. The process of claim 36 wherein (e) comprises forming an optical switch.

40. The process of claim 33 wherein (e) comprises forming a switch.

41. The process of claim 33 wherein (e) comprises forming a variable capacitance structure.

42. The process of claim 38 further comprising:
(f) forming an amplifier in the monocrystalline compound semiconductor layer.

43. The process of claim 36 wherein (e) comprises forming a temperature control structure in the monocrystalline silicon substrate.

44. The process of claim 34 wherein (e) comprises forming a switch in the monocrystalline silicon substrate connected transmit and receive components in the monocrystalline compound semiconductor layer.

45. The process of claim 27 wherein (d) comprises forming a gallium arsenide layer.

46. The process of claim 27 wherein (d) comprises forming a indium phosphide layer.
